(19) United States
(12) Patent Application Publication
(10) Pub. No.: US 2026/0211555 A1
(43) Pub. Date: Jul. 23, 2026

(54) MEMORY DEVICE INCLUDING SKEW MONITORING MODULE AND OPERATION MEHOD THEREOF

(71) Applicant: Samsung Electronics Co., Ltd., Suwon-si (KR)

(72) Inventors: Sanghun LEE, Suwon-si (KR); Hwan Seok KU, Suwon-si (KR); Chiweon YOON, Suwon-si (KR); Dongkyu JUNG, Suwon-si (KR); Youngmin JO, Suwon-si (KR)

(21) Appl. No.: 19/410,360

(22) Filed: Dec. 5, 2025

(30) Foreign Application Priority Data
Jan. 23, 2025 (KR) 10-2025-0010034

(51) Int. Cl. G06F 3/06

(52) U.S. Cl. CPC G06F 3/0614; G06F 3/0653; G06F 3/0679

(57) ABSTRACT

Disclosed is a memory device which comprises a memory cell array; and a monitoring module comprising: a skew detection circuit configured to detect a first skew value between a data signal and a data strobe signal, a reference skew latch circuit configured to store a reference skew value, and a skew comparison circuit configured to: compare the first skew value and the reference skew value, to obtain a comparison result, and generate a data strobe training flag based on the comparison result.

### CROSS-REFERENCE TO RELATED APPLICATION

This application claims priority under 35 U.S.C. § 119 to Korean Patent Application No. 10-2025-0010034 filed on January 23, 2025, in the Korean Intellectual Property Office, the entirety of which is incorporated by reference herein.

### BACKGROUND

A memory device including a NAND flash memory may use a data signal and a data strobe signal (DQS) to transmit and receive data. The memory device may capture the data signal at the timing when the data strobe signal is received and may determine data of the data signal. A skew may occur between the data signal and the data strobe signal of the memory device, depending on how the memory device is implemented.

To remove or reduce the above skew, a controller which controls the memory device may periodically retrain the data strobe signal. While the controller retrains the data strobe signal, data exchange between the controller and the memory device may be interrupted. The operation in which the controller periodically retrains the data strobe signal may reduce the efficiency of input/output between the controller and the memory device.

### SUMMARY

Some aspects of the present disclosure provide memory devices configured whether training of a data strobe signal is required, based on a skew monitoring module. and notify a controller the training of the data strobe signal is required when the training of the data strobe signal is required.

According to some implementations, a memory device comprises: a memory cell array; and a monitoring module comprising: a skew detection circuit configured to detect a first skew value between a data signal and a data strobe signal, a reference skew latch circuit configured to store a reference skew value, and a skew comparison circuit configured to: compare the first skew value and the reference skew value, to obtain a comparison result, and generate a data strobe training flag based on the comparison result.

According to some implementations, an operation method of a memory device comprises: performing data strobe training to generate a reference skew value between a data signal and a data strobe signal; detecting a first skew value between the data signal and the data strobe signal; comparing the reference skew value and the first skew value; and based on a difference between the reference skew value and the first skew value being greater than a threshold value, setting a data strobe training flag to a level indicating that data strobe training is to be performed.

According to some implementation, a storage device comprises: a memory device configured to store data, wherein the memory device comprises a monitoring module; and a controller configured to control the memory device and to exchange a data signal and a data strobe signal with the memory device, wherein the monitoring module is configured to: generate a reference skew value between the data signal and the data strobe signal, wherein the reference skew value is generated as a result of data strobe training performed by the memory device, detect a first skew value between the data signal and the data strobe signal, and generate a data strobe training flag based on a comparison between the reference skew value and the first skew value, wherein the controller is configured to provide a data strobe training command to the memory device based on the data strobe training flag, and wherein the monitoring module is configured to perform additional data strobe training in response to the data strobe training command.

### BRIEF DESCRIPTION OF THE DRAWINGS

FIG. 1 is a block diagram illustrating an example of a storage device.

FIG. 2 is a diagram illustrating an example of a data signal and a data strobe signal.

FIG. 3 is a block diagram illustrating an example of a memory device of FIG. 1.

FIG. 4 is a flowchart illustrating an example of an operation method of a tDQS2DQ monitoring module.

FIG. 5 is a block diagram illustrating an example of a tDQS2DQ monitoring module.

FIG. 6 is a block diagram illustrating an example of a skew detection circuit.

FIG. 7 is a flowchart illustrating an example of an operation method of a memory device.

FIG. 8 is a timing diagram illustrating how signals are changed by an operation of a tDQS2DQ monitoring module over time.

FIG. 9 is a circuit diagram illustrating an example of a memory block.

FIG. 10 is a block diagram illustrating an example of a storage device.

FIG. 11 is a block diagram illustrating an example of a host-storage system.

### DETAILED DESCRIPTION

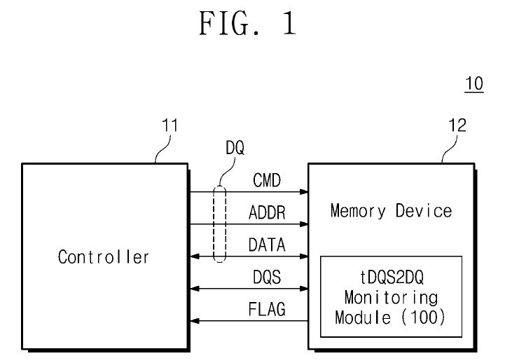

FIG. 1 is a block diagram illustrating an example of a storage device. Referring to FIG. 1, a storage device 10 may include a controller 11 and a memory device 12. The storage device 10 may be included in various types of electronic devices or systems and may store data which are used in the operation of the electronic device or system, and/or data which are generated in the operation of the electronic device or system. For example, the storage device 10 may be included in an electronic device or a cloud system, such as a personal computer (PC), a smartphone, a laptop PC, a tablet PC, an Internet-of-Things (IoT) device, a server, a data center, or an automotive system.

The controller 11 may control operations of the storage device 10. In some implementations, the controller 11 may manage a data input to the memory device 12 or a data output from the memory device 12. In some implementations, the controller 11 may receive a request from a host, may perform an operation corresponding to the request or an operation indicated by the request, and may transmit a response according to the request to the host.

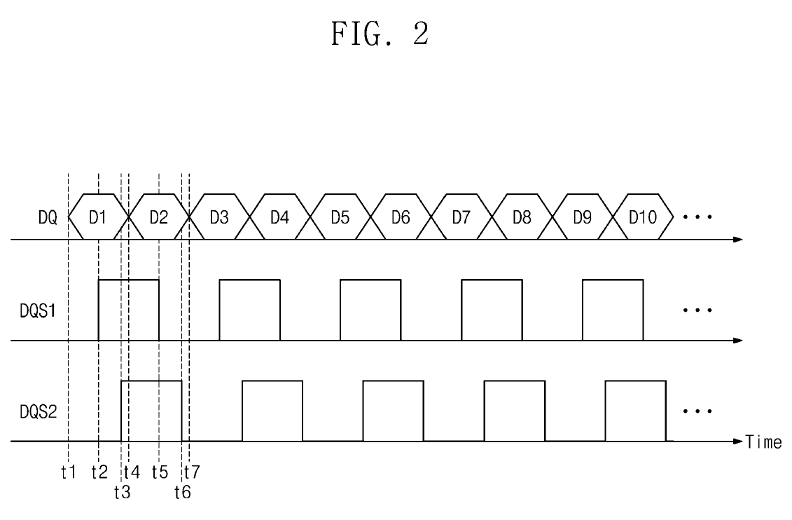

In some implementations, the controller 11 may control the memory device 12, based on one or more signals. For example, the controller 11 may control the memory device 12, based on a command CMD indicating an operation which the memory device 12 will perform or an address value ADDR indicating a location at which the operation will be performed. In some implementations, the controller 11 may transmit the command CMD or the address value ADDR to the memory device 12 through a data signal DQ. In some implementations, the controller 11 and the memory device 12 may exchange data “DATA” through the data signal DQ. A data strobe signal DQS may be a signal which is used as a criterion for determining or deciding a value or data of the command CMD, the address value ADDR, or the data “DATA” included in the data signal DQ. How the data signal DQ and the data strobe signal DQS change over time, and an example of the data signal DQ and the data strobe signal DQS, will be described in detail with reference to FIG. 2.

The communication between the controller 11 and the memory device 12 may be performed based on a standard or a protocol defined in advance. For example, the communication between the controller 11 and the memory device 12 may be performed based on the toggle standard or the open NAND flash interface (ONFI) standard.

The memory device 12 may store data. In some implementations, the memory device 12 may include a NAND flash memory device. For example, the memory device 12 may store data in a plurality of NAND flash memory cells. The following description is based on an example in which the memory device 12 is implemented based on NAND flash memory cells, but the memory type is not limited thereto. It should be understood that implementations in which the memory device 12 is implemented with various kinds of nonvolatile memory cells also belong in the scope of the present disclosure.

Referring to FIG. 1, the memory device 12 may include a tDQS2DQ monitoring module 100. The tDQS2DQ monitoring module 100 may monitor a skew between the data signal DQ and the data strobe signal DQS. In some implementations, the tDQS2DQ monitoring module 100 may periodically monitor the skew between the data signal DQ and the data strobe signal DQS. For example, the tDQS2DQ monitoring module 100 may periodically monitor the skew between the data signal DQ and the data strobe signal DQS, based on periodically measuring or detecting the skew between the data signal DQ and the data strobe signal DQS.

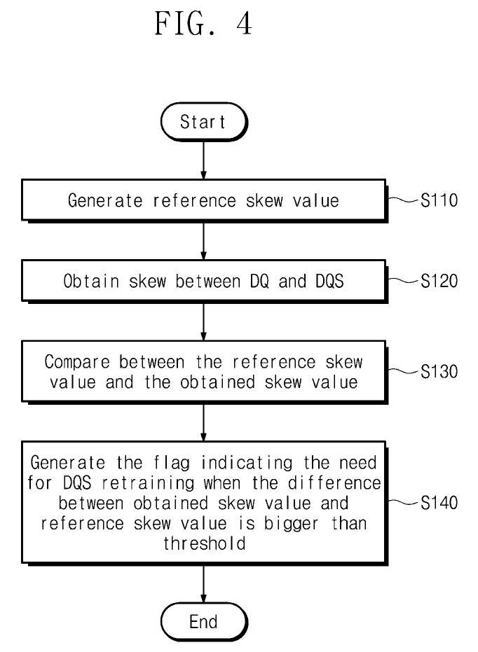

The tDQS2DQ monitoring module 100 may detect the necessity for DQS training. In some implementations, when the skew between the data signal DQ and the data strobe signal DQS is greater than a threshold value or is out of a threshold range, the tDQS2DQ monitoring module 100 may determine that the DQS training is required, or may determine to perform DQS training. In some implementations, the tDQS2DQ monitoring module 100 may transmit, to the controller 11, a flag “FLAG” indicating that the DQS training is required or that it has been determined to perform DQS training. The tDQS2DQ monitoring module 100 will be described in detail with reference to FIGS. 4 to 8.

In some implementations, the flag “FLAG” may be included in the data signal DQ as a response to the specific command CMD so as to be transmitted to the controller 11. For example, the flag “FLAG” may be included in the data signal DQ generated as a response to status read command or a command similar thereto, so as to be transmitted to the controller 11. As another example, the flag “FLAG” may be provided to the controller 11 through a separate signal line. However, this is provided as an example, and the scope of the present disclosure is not limited thereto.

FIG. 2 is a diagram illustrating an example of a data signal and a data strobe signal, e.g., the signals of FIG. 1. Referring to FIG. 2, an example of changes of the data signal DQ, a first data strobe signal DQS1, and a second data strobe signal DQS2 over time is illustrated. In FIG. 2, description will be given based for the case where the memory device 12 receives the signals of FIG. 2, but it should be understood that the description applies identically or similarly when the controller 11 receives the signals of FIG. 2.

The data signal DQ may be sequentially changed based on first to tenth data D1 to D10. In some implementations, each of the first to tenth data D1 to D10 may include values of a plurality of bits. In some implementations, when the data of the data signal DQ is changed, values of at least some of the plurality of bits may be simultaneously changed.

The data strobe signals DQS1 and DQS2 may be signals which are used as a criterion for determining data included in the data signal DQ. In some implementations, the memory device 12 may determine data included in the data signal DQ in response to rising edges and falling edges of the data strobe signals DQS1 and DQS2.

The first data strobe signal DQS1 may be a data strobe signal which has a zero skew with respect to the data signal DQ. In some implementations, the edge timing of the first data strobe signal DQS1 may be positioned at the center of the timing when the level of the data signal DQ is changed (i.e., may be center-aligned). For example, the rising edge of the first data strobe signal DQS1 may be generated at a second time point t2 corresponding to the center between a first time point t1 and a fourth time point t4, and the falling edge of the first data strobe signal DQS1 may be generated at a fifth time point t5 corresponding to the center between a fourth time point t4 and a seventh time point t7. When the memory device 12 determines the data of the data signal DQ depending on the first data strobe signal DQS1, because the memory device 12 determines the data at the center of time points at which the data signal DQ is changed, the memory device 12 may accurately determine the data which the data signal DQ indicates.

The second data strobe signal DQS2 may be a data strobe signal which has a non-zero skew with respect to the data signal DQ. In some implementations, the edge timing of the second data strobe signal DQS2 may not be positioned at the center of the timing when the level of the data signal DQ is changed. For example, the rising edge of the second data strobe signal DQS2 may be generated at a third time point t3 that is between (e.g., at the center of) the second time point t2 and the fourth time point t4, and the falling edge of the second data strobe signal DQS2 may be generated at a sixth time point t6 that is between (e.g., at the center of) the fifth point t5 and the seventh time point t7.

When the memory device 12 determines the data of the data signal DQ depending on the second data strobe signal DQS2, because the memory device 12 determines the data at a time point different from the center of the time points at which the data signal DQ is changed, the memory device 12 may abnormally determine at least some of bits included in the data signal DQ. When the skew between the second data strobe signal DQS2 and the data signal DQ is greater than or equal to a threshold value, an error may occur in all or a portion of the data determined from the data signal DQ. In some implementations, depending on a factor such as a change in an operation or PVT condition of the storage device 10, a value of the skew between the data signal DQ and the data strobe signal DQS may change. Accordingly, method and devices capable of maintaining the skew between the data strobe signal DQS and the data signal DQ at a given value or less, such that data included in the data signal DQ are accurately determined, are advantageous.

In some implementations, to manage the skew between the data signal DQ and the data strobe signal DQS at the threshold value or less, the controller 11 may transmit a command CMD indicating data strobe signal (DQS) training to the memory device 12. In some cases, the controller 11 and the memory device 12 may be incapable of exchanging the data “DATA” while the DQS training is performed. In some implementations, the memory device 12 may notify the controller 11 that the DQS training is required, through the tDQS2DQ monitoring module 100, and the controller 11 may issue the command CMD indicating the DQS training (or retraining) in response to the notification.

Example of operation of the tDQS2DQ monitoring module 100 will be described in detail with reference to FIGS. 4 to 8. In some implementations, through the flag “FLAG”, the memory device 12 may notify the controller 11 that the DQS training is required. For example, the flag “FLAG” may include a DQS training flag, may include a DQS retraining flag, or may be one of the DQS training flag and the DQS retraining flag.

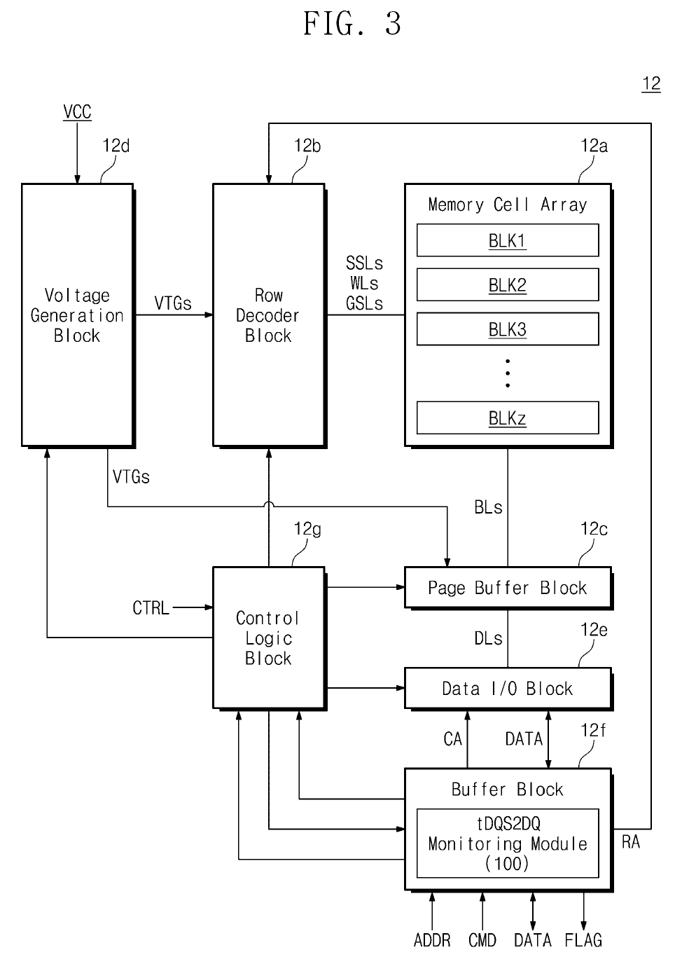

FIG. 3 is a block diagram illustrating an example of a memory device (e.g., the memory device 12 of FIG. 1) in detail. Referring to FIG. 3, the memory device 12 may include a memory cell array 12a, a row decoder block 12b, a page buffer block 12c, a voltage generation block 12d, a data input/output (I/O) block 12e, a buffer block 12f, and a control logic block 12g. The memory device 12 will be described in detail with reference to FIG. 3.

In some implementations, the memory device 12 may include memory cells of an arbitrary structure. For example, the memory device 12 may include NAND flash memory cells. Below, for convenience, the description will be given based on the case where the memory device 12 is a NAND flash memory device, but the scope of the present disclosure is not limited thereto. For example, it should be understood that implementations in which the memory device 12 includes any other type of memory cells, such as a ferro-electric random access memory (FeRAM) cell, a magnetic RAM (MRAM) cell, or a spin torque transfer MRAM (STTMRAM) cell, are also within the scope of this disclosure.

The memory cell array 12a may include a plurality of memory blocks BLK1 to BLKz. Each of the memory blocks BLK1 to BLKz may include a plurality of memory cells. Each of the memory blocks BLK1 to BLKz may be connected to the row decoder block 12b through at least one ground selection line GSL, word lines WLs, and at least one string selection line SSL. Some of the word lines WLs may be used as dummy word lines. Each of the memory blocks BLK1 to BLKz may be connected to the page buffer block 12c through a plurality of bit lines BLs. The plurality of memory blocks BLK1 to BLKz may be connected in common to the plurality of bit lines BLs.

In some implementations, each of the plurality of memory blocks BLK1 to BLKz may be a unit of the erase operation. The memory cells belonging to each of the memory blocks BLK1 to BLKz may be simultaneously erased. In some implementations, each of the plurality of memory blocks BLK1 to BLKz may be divided into sub-blocks. Each of the plurality of sub-blocks may be a unit of the erase operation, and a plurality of memory cells belonging to each sub-block may be simultaneously erased. Below, the erase unit may indicate the unit of the erase operation, and the erase unit may correspond to a memory block or a sub-block.

Each of the memory blocks BLK1 to BLKz may include a plurality of pages. The plurality of pages may be respectively connected to the word lines WLs. Each of the pages may be a unit of the write operation.

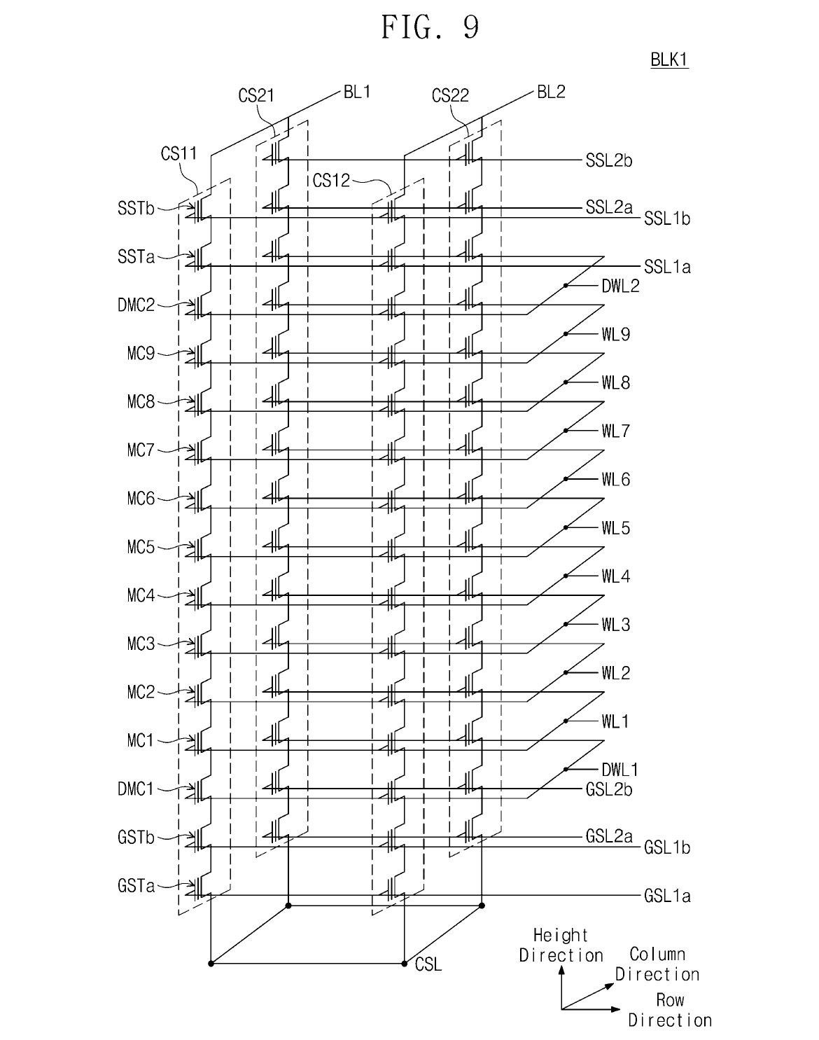

Bits which are written in memory cells of one page may constitute logical pages. For example, when three bits are written in one memory cell, one physical page may include three logical pages. For another example, when one bit is written in one memory cell, one physical page may include one logical page. The logical page(s) or the physical page may be a unit of the read operation. The memory blocks BLK1 to BLKz will be described in detail with reference to FIG. 9.

The row decoder block 12b may decode a row address RA received from the buffer block 12f and may control voltages to be applied to the string selection lines SSL, the word lines WLs, and the ground selection lines GSL depending on the decoded row address RA.

The page buffer block 12c may be connected to the memory cell array 12a through the plurality of bit lines BLs. The page buffer block 12c may be connected to the data input/output block 12e through a plurality of data lines DLs. The page buffer block 12c may operate under control of the control logic block 12g.

When the memory device 12 performs the program operation, the page buffer block 12c may store data to be written in memory cells. The page buffer block 12c may apply a corresponding voltage to each of the plurality of bit lines BLs, based on the data stored therein. When the memory device 12 performs the read operation or performs a verifying read operation of the program operation or the erase operation, the page buffer block 12c may sense a voltage of each of the bit lines BLs and may store a sensing result.

The voltage generation block 12d may generate various voltages which are used for the operation of the memory device 12. In some implementations, the voltage generation block 12d may generate a plurality of voltages, based on a power supply voltage VCC. For example, the voltage generation block 12d may convert or process the power supply voltage VCC to generate voltages VTGs and may provide the generated voltages VTGs to the row decoder block 12b or the page buffer block 12c. In some implementations, the voltage generation block 12d may operate under control of the control logic block 12g.

The data input/output block 12e may be connected to the page buffer block 12c through the plurality of data lines DLs. The data input/output block 12e may receive a column address CA from the buffer block 12f. The data input/output block 12e may output the data read by the page buffer block 12c to the buffer block 12f depending on the column address CA. The data input/output block 12e may transfer the data received from the buffer block 12f to the page buffer block 12c, based on the column address CA.

The buffer block 12f may receive the command CMD or the address value ADDR from an external device (e.g., the controller 11 of FIG. 1) and may exchange the data “DATA” with the external device. The buffer block 12f may operate under control of the control logic block 12g. In some implementations, the data “DATA” may include the data signal DQ or the data strobe signal DQS of FIGS. 1 and 2.

The buffer block 12f may transfer the command CMD to the control logic block 12g, may transfer the row address RA of the address value ADDR to the row decoder block 12b, and may transfer the column address CA of the address value ADDR to the data input/output block 12e. The buffer block 12f may exchange the data “DATA” with the data input/output block 12e.

In some implementations, the buffer block 12f may include the tDQS2DQ monitoring module 100 of FIG. 1. For example, the buffer block 12f may transmit the flag “FLAG” generated by the operation of the tDQS2DQ monitoring module 100 to the controller 11. An example in which the buffer block 12f includes the tDQS2DQ monitoring module 100 is described with reference to FIG. 3, but the scope of the present disclosure is not limited thereto. For example, it should be understood that implementations in which the tDQS2DQ monitoring module 100 is included in any other block such as the data input/output block 12e, or the control logic block 12g, also belong to the scope of the present disclosure. For example, the tDQS2DQ monitoring module 100 may be included in the control logic block 12g, and the tDQS2DQ monitoring module 100 may transmit the flag “FLAG” to the controller 11 through the buffer block 12f.

The control logic block 12g may receive a control signal CTRL through the external device (e.g., the controller 11 of FIG. 1). The control logic block 12g may allow the buffer block 12f to route the command CMD, the address value ADDR, and the data “DATA”. The control logic block 12g may decode the command CMD received from the buffer block 12f and may control the memory device 12 based on the decoded command.

In some implementations, the memory device 12 may be manufactured in a bonding method. The memory cell array 12a may be manufactured by using a first wafer, and the row decoder block 12b, the page buffer block 12c, the data input/output block 12e, the buffer block 12f, and the control logic block 12g may be manufactured by using a second wafer. The memory device 12 may be implemented by coupling the first wafer and the second wafer such that an upper surface of the first wafer and an upper surface of the second wafer face each other. In some implementations, the memory device 12 may be manufactured in a cell over peri (COP) method. A peripheral circuit including the row decoder block 12b, the page buffer block 12c, the data input/output block 12e, the buffer block 12f, and the control logic block 12g may be manufactured on a wafer. The memory cell array 12a may be implemented over the peripheral circuit. The peripheral circuit and the memory cell array 12a may be connected by using through vias.

FIG. 4 is a flowchart illustrating an example of an operation method of a tDQS2DQ monitoring module, e.g., the tDQS2DQ monitoring module of FIGS. 1 and 3.

In operation S110, the tDQS2DQ monitoring module 100 may generate a reference skew value. The reference skew value may be a first skew value between a data signal and a data strobe signal after a data strobe signal training or retraining operation or may correspond to the first skew value. In some implementations, the tDQS2DQ monitoring module 100 may generate the reference skew value in response to an instruction indicating training. For example, the tDQS2DQ monitoring module 100 may generate the reference skew value in response to the command CMD which the memory device 12 receives and indicates the training of the data strobe signal.

In operation S120, the tDQS2DQ monitoring module 100 may obtain the skew between the data signal and the data strobe signal. In some implementations, the tDQS2DQ monitoring module 100 may obtain the skew value between the data signal and the data strobe signal. For example, after the tDQS2DQ monitoring module 100 generates the reference skew value, the tDQS2DQ monitoring module 100 may periodically measure the skew between the data signal and the data strobe signal and may obtain the skew value between the data signal and the data strobe signal.

In operation S130, the tDQS2DQ monitoring module 100 may compare the reference skew value and the obtained skew value. In some implementations, the tDQS2DQ monitoring module 100 may determine whether a difference between the reference skew value and the obtained skew value belongs to the threshold range or otherwise satisfies a threshold condition. For example, the tDQS2DQ monitoring module 100 may determine whether the difference between the reference skew value and the obtained skew value is greater than a threshold value.

When the difference between the reference skew value and the obtained skew value is greater than the threshold value, in operation S140, the tDQS2DQ monitoring module 100 may generate a flag indicating that DQS retraining is required. In some implementations, the flag “FLAG” which the tDQS2DQ monitoring module 100 generates may be transmitted to the controller 11. For example, in operation S130, the tDQS2DQ monitoring module 100 may determine that the difference between the reference skew value and the obtained skew value is greater than the threshold value; depending on the determination, the tDQS2DQ monitoring module 100 may generate the flag “FLAG” so as to be transmitted to the controller 11.

In response to the flag “FLAG” in operation S140, the controller 11 may issue the command CMD indicating the necessity of training the data strobe signal DQS, so as to be transmitted to the memory device 12. The memory device 12 may receive the command CMD indicating the training of the data strobe signal DQS and may train the data strobe signal DQS. The memory device 12 may adjust the skew between the data signal DQ and the data strobe signal DQS through the training of the data strobe signal DQS. In this case, the adjusted skew value may be the same as the existing reference skew value, or the adjusted skew value may be used as a new reference skew value.

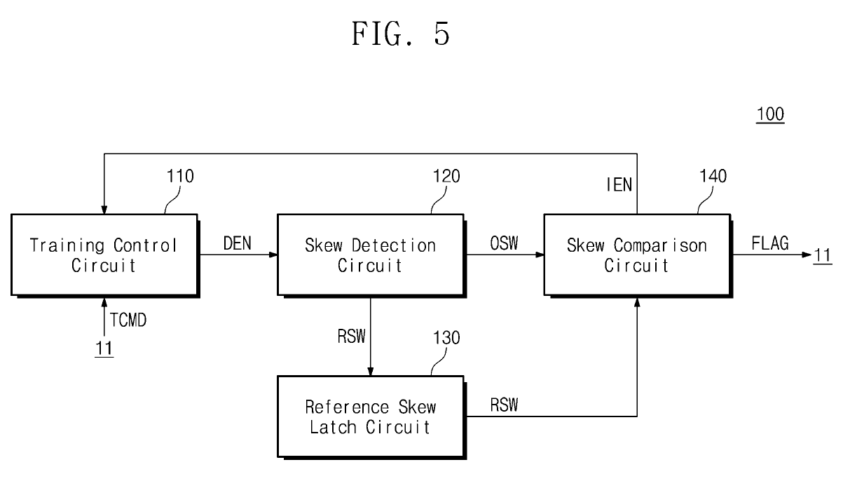

FIG. 5 is a block diagram illustrating an example of a tDQS2DQ monitoring module 100 (e.g., of FIG. 1) in detail. Referring to FIG. 5, the tDQS2DQ monitoring module 100 may include a training control circuit 110, a skew detection circuit 120, a reference skew latch circuit 130, and a skew comparison circuit 140.

The training control circuit 110 may control operations of the tDQS2DQ monitoring module 100. In some implementations, the training control circuit 110 may control the training of the data strobe signal DQS. For example, the training control circuit 110 may control the training or retraining of the data strobe signal DQS in response to the command CMD from the controller 11.

The training control circuit 110 may control an operation of detecting the skew between the data signal DQ and the data strobe signal DQS. In some implementations, the training control circuit 110 may control the tDQS2DQ monitoring module 100 in response to a trace command TCMD such that the skew between the data signal DQ and the data strobe signal DQS is detected. For example, the training control circuit 110 may start the operation of detecting the skew between the data signal DQ and the data strobe signal DQS by transmitting a detection enable signal DEN to the skew detection circuit 120 in response to the trace command TCMD or changing a level of the detection enable signal DEN in response to the trace command TCMD.

In some implementations, the trace command TCMD may correspond to a command indicating DQS training. For example, the trace command TCMD may be a command indicating DQS training or may be included in the command indicating DQS training. In some implementations, the trace command TCMD may not correspond to the command indicating DQS training. For example, the trace command TCMD and the command indicating DQS training may constitute a separate command.

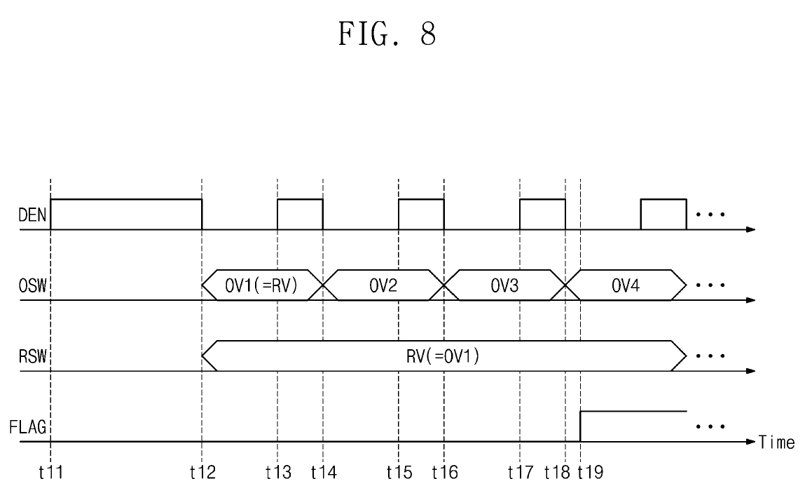

The training control circuit 110 may periodically generate the detection enable signal DEN or may periodically change the level of the detection enable signal DEN, to initiate skew detection. In some implementations, in response to an internal enable signal IEN received from the skew comparison circuit 140 or the trace command TCMD received from the controller 11, the training control circuit 110 may periodically generate the detection enable signal DEN or may periodically change the level of the detection enable signal DEN, to initiate skew detection. The detection enable signal DEN will be described in detail with reference to FIG. 8.

The skew detection circuit 120 may detect the skew between the data signal DQ and the data strobe signal DQS. The skew detection circuit 120 may detect the skew between the data signal DQ and the data strobe signal DQS and may generate a reference skew value RSW or an obtained skew value OSW. In some implementations, the reference skew value RSW may be a skew between the data signal DQ and the data strobe signal DQS after or immediately after the DQS training, or may correspond to (e.g., indicate) that skew.

In some implementations, the skew detection circuit 120 may detect the skew between the data signal DQ and the data strobe signal DQS in response to the detection enable signal DEN. For example, the skew detection circuit 120 may generate the reference skew value RSW and the obtained skew value OSW in response to the detection enable signal DEN generated according to the trace command TCMD. As example, the skew detection circuit 120 may generate the obtained skew value OSW in response to the detection enable signal DEN generated according to the internal enable signal IEN. The skew detection circuit 120 may provide the reference skew value RSW to the reference skew latch circuit 130 and may provide the obtained skew value OSW to the skew comparison circuit 140.

The reference skew latch circuit 130 may store the reference skew value RSW. For example, the reference skew latch circuit 130 may store the reference skew value RSW received from the skew detection circuit 120. The reference skew latch circuit 130 may provide the reference skew value RSW to the skew comparison circuit 140.

The skew comparison circuit 140 may compare the obtained skew value OSW and the reference skew value RSW. In some implementations, the skew comparison circuit 140 may determine whether a difference between the obtained skew value OSW and the reference skew value RSW is greater than the threshold value or otherwise satisfies a threshold condition. When the difference between the obtained skew value OSW and the reference skew value RSW is greater than the threshold value, the skew comparison circuit 140 may generate the flag “FLAG” or may change the level of the flag “FLAG”. When the difference between the obtained skew value OSW and the reference skew value RSW is not greater than the threshold value, the skew comparison circuit 140 may generate the internal enable signal IEN and may provide the internal enable signal IEN to the training control circuit 110.

The flag “FLAG”, the obtained skew value OSW, and the reference skew value RSW will be described in detail with reference to FIG. 8. The obtained skew value OSW and the reference skew value RSW may be data of an arbitrary format. For example, the obtained skew value OSW and the reference skew value RSW may have the format of a binary code with a 16-bit length. In this case, the skew comparison circuit 140 may include a binary comparison circuit which generates the flag “FLAG” or changes the level of the flag “FLAG”, when the difference between the obtained skew value OSW and the reference skew value RSW is greater than the threshold value.

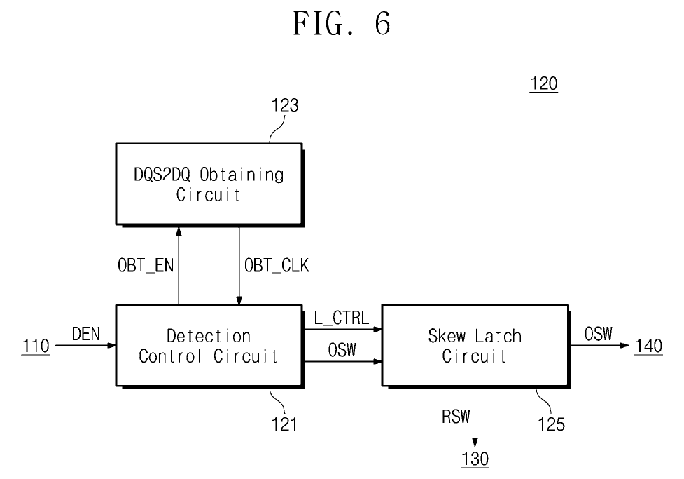

FIG. 6 is a block diagram illustrating an example of a skew detection circuit 120 (e.g., of FIG. 5) in detail. Referring to FIG. 6, the skew detection circuit 120 may include a detection control circuit 121, a DQS2DQ obtaining circuit 123, and a skew latch circuit 125.

The detection control circuit 121 may overall control a skew detection operation. In some implementations, the detection control circuit 121 may control the skew detection operation in response to the detection enable signal DEN. The detection control circuit 121 may generate various control signals in response to the detection enable signal DEN. For example, the detection control circuit 121 may generate an obtaining enable signal OBT_EN and may provide the obtaining enable signal OBT_EN to the DQS2DQ obtaining circuit 123, and the detection control circuit 121 may generate a latch control signal L_CTRL and may provide the latch control signal L_CTRL to the skew latch circuit 125.

In some implementations, the detection control circuit 121 may generate the obtained skew value OSW, based on an obtaining clock signal OBT_CLK. The obtaining clock signal OBT_CLK may correspond to the skew between the data signal DQ and the data strobe signal DQS and may have a clock signal waveform. For example, the detection control circuit 121 may count the obtaining clock signal OBT_CLK (e.g., the number of signal edges) to generate the obtained skew value OSW. In some implementations, the obtained skew value OSW which the detection control circuit 121 generates for the first time after the DQS training may correspond to the reference skew value RSW of FIG. 5.

The detection control circuit 121 may control the skew latch circuit 125. In some implementations, the detection control circuit 121 may control the skew latch circuit 125 through the latch control signal L_CTRL. For example, through the latch control signal L_CTRL, the detection control circuit 121 may control the skew latch circuit 125 to store the obtained skew value OSW. As another example, through the latch control signal L_CTRL, the detection control circuit 121 may control the skew latch circuit 125 such that the reference skew value RSW is transferred to the reference skew latch circuit 130 of FIG. 5.

The DQS2DQ obtaining circuit 123 may detect the skew between the data signal DQ and the data strobe signal DQS. In some implementations, the DQS2DQ obtaining circuit 123 may generate the obtaining clock signal OBT_CLK corresponding to the skew between the data signal DQ and the data strobe signal DQS. In some implementations, the DQS2DQ obtaining circuit 123 may start the operation of detecting the skew between the data signal DQ and the data strobe signal DQS in response to the obtaining enable signal OBT_EN. For example, in response to the obtaining enable signal OBT_EN, the DQS2DQ obtaining circuit 123 may generate the obtaining clock signal OBT_CLK and may transmit the generated obtaining clock signal OBT_CLK to the detection control circuit 121.

The skew latch circuit 125 may store a skew value. For example, the skew latch circuit 125 may store the received obtained skew value OSW. In some implementations, the obtained skew value OSW which is generated for the first time after the DQS training may correspond to the reference skew value RSW or may be the same as the reference skew value RSW. The skew latch circuit 125 may provide the reference skew value RSW to the reference skew latch circuit 130 of FIG. 5 and may provide the obtained skew value OSW to the skew comparison circuit 140.

In FIGS. 5 and 6, it should be understood that the division of the respective circuits is provided as an example. The division of the circuits of FIGS. 5 and 6 represents functions of the circuits, and it should be understood that implementations in which two or more of the illustrated circuits are implemented with common hardware, and implementations in which one circuit is implemented with two or more hardware elements, also belong to the scope of the present disclosure.

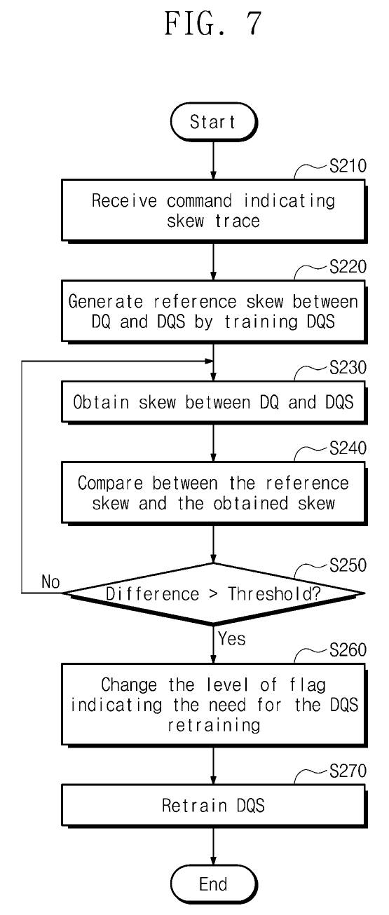

FIG. 7 is a flowchart illustrating an example of an operation method of a memory device of FIGS. 1 to 6.

In operation S210, the memory device 12 may receive a command indicating a skew trace. In some implementations, the skew trace may indicate to trace or monitor the skew between the data signal DQ and the data strobe signal DQS (e.g., periodically). For example, the memory device 12 may receive the trace command TCMD of FIG. 5 from the controller 11 of FIG. 1.

In operation S220, the memory device 12 may generate the reference skew value between the data signal DQ and the data strobe signal DQS through DQS training. For example, the memory device 12 may perform DQS training and may generate the reference skew value RSW through the tDQS2DQ monitoring module 100. For example, the tDQS2DQ monitoring module 100 may generate the reference skew value RSW through the skew detection circuit 120 and may store the generated reference skew value RSW in the reference skew latch circuit 130.

In operation S230, the memory device 12 may obtain the skew between the data signal DQ and the data strobe signal DQS. For example, the tDQS2DQ monitoring module 100 may detect a skew value between the data signal DQ and the data strobe signal DQS to generate the obtained skew value OSW. The tDQS2DQ monitoring module 100 may store the generated obtained skew value OSW in the skew latch circuit 125.

In operation S240, the memory device 12 may compare the reference skew value OSW and the obtained skew value OSW. In some implementations, the memory device 12 may determine whether a difference between the reference skew value RSW and the obtained skew value OSW is greater than the threshold value. For example, the tDQS2DQ monitoring module 100 may compare the reference skew value RSW and the obtained skew value OSW through the skew comparison circuit 140.

In operation S250, the memory device 12 may determine a next operation, based on a magnitude relationship between the difference between the obtained skew value OSW and the reference skew value RSW and the threshold value. When the difference between the obtained skew value OSW and the reference skew value RSW is greater than the threshold value, the memory device 12 may proceed to operation S260. When the difference between the obtained skew value OSW and the reference skew value RSW is not greater than the threshold value, the memory device 12 may return to operation S230.

In operation S260, the memory device 12 may change a level of a flag indicating that the DQS training is required. For example, the memory device 12 may change the level of the flag “FLAG” from a low level LOW to a high level HIGH to indicate that the DQS training is required.

In operation S270, the memory device 12 may perform the DQS training. In some implementations, the memory device 12 may perform the DQS training in response to the command CMD indicating the DQS training of the controller 11. After operation S270, the memory device 12 may terminate an operation. After operation S270, the memory device 12 may return to operation S210 in response to a command (e.g., the trace command TCMD of FIG. 5) of the controller 11.

Because the controller 11 is capable of determining the DQS training based on the flag “FLAG” according to the operation of FIG. 7, the controller 11 may not periodically issue the command CMD for DQS training. For example, DQS training may be performed only when necessary, based on measured skew values. Accordingly, a time during which the communication between the controller 11 and the memory device 12 is interrupted due to the command CMD for DQS training may decrease. Accordingly, the input/output (I/O) efficiency between the controller 11 and the memory device 12 may be improved, and a time necessary for the DQS training may decrease.

FIG. 8 is a timing diagram illustrating how signals are changed by an operation of a tDQS2DQ monitoring module (e.g., of FIGS. 5 and 6) over time.

At an 11th time point t11, the level of the detection enable signal DEN may transition to the high level HIGH. In some implementations, at the 11th time point t11, the detection enable signal DEN may transition to the high level HIGH in response to the trace command TCMD. In some implementations, from a time period from t11 to t12, the memory device 12 may perform DQS training. After the DQS training, the memory device 12 may obtain a skew value between the data signal DQ and the data strobe signal DQS. The skew value generated in the time period from t11 to t12 may be the reference skew value RSW and the obtained skew value OSW.

At the 12th time point t12, the reference skew value OSW and the obtained skew value OSW may be changed. At the 12th time point t12, the obtained skew value OSW may be changed to a first obtaining value OV1. The reference skew value RSW may be changed to a reference value RV at the 12th time point t12, and the reference value RV may be the same as the first obtaining value OV1. At the 12th time point t12, the level of the detection enable signal DEN may be changed to the low level LOW.

In a time period from t12 to t13, the tDQS2DQ monitoring module 100 may compare the reference skew value RSW and the obtained skew value OSW. In some implementations, the skew comparison circuit 140 may generate the internal enable signal IEN based on a comparison result, so as to be transmitted to the training control circuit 110. At the 13th time point t13, the training control circuit 110 may change the level of the detection enable signal DEN to the high level HIGH in response to the internal enable signal IEN.

From a time period from t13 to t14, the tDQS2DQ monitoring module 100 may detect the skew between the data signal DQ and the data strobe signal DQS. For example, in response to the detection enable signal DEN at the 13th time point t13, the skew detection circuit 120 may detect the skew between the data signal DQ and the data strobe signal DQS. At the 14th time pointt14, the tDQS2DQ monitoring module 100 may change the obtained skew value OSW to the skew value detected in the time period from t13 to t14. For example, at the 14th time point t14, the obtained skew value OSW may be changed to a second obtaining value OV2. At the 14th time point t14, the level of the detection enable signal DEN may be changed to the low level LOW.

In a time period from t14 to t15, the tDQS2DQ monitoring module 100 may compare the obtained skew value OSW and the reference skew value RSW. A difference between the second obtaining value OV2 and the reference value RV may not be greater than the threshold value or may belong to the threshold range, and thus, the flag “FLAG” may maintain the low level LOW. The skew comparison circuit 140 may generate the internal enable signal IEN based on a comparison result in the time period from t14 to t15, so as to be transmitted to the training control circuit 110. At the 15th time point t15, the training control circuit 110 may change the level of the detection enable signal DEN to the high level HIGH in response to the internal enable signal IEN.

From a time period from t15 to t16, the tDQS2DQ monitoring module 100 may detect the skew between the data signal DQ and the data strobe signal DQS. For example, in response to the detection enable signal DEN at the 15th time point t15, the skew detection circuit 120 may detect the skew between the data signal DQ and the data strobe signal DQS. At the 16th time point t16, the tDQS2DQ monitoring module 100 may change the obtained skew value OSW to the skew value detected in the time period from t15 to t16. For example, at the 16th time point t16, the obtained skew value OSW may be changed to a third obtaining value OV3. At the 16th time point t16, the level of the detection enable signal DEN may be changed to the low level LOW.

In a time period from t16 to t17, the tDQS2DQ monitoring module 100 may compare the obtained skew value OSW and the reference skew value RSW. A difference between the third obtaining value OV3 and the reference value RV may not be greater than the threshold value or may belong to the threshold range, and thus, the flag “FLAG” may maintain the low level LOW. The skew comparison circuit 140 may generate the internal enable signal IEN based on a comparison result in the time period from t16 to t17, so as to be transmitted to the training control circuit 110. At the 17th time point t17, the training control circuit 110 may change the level of the detection enable signal DEN to the high level HIGH in response to the internal enable signal IEN.

From a time period from t17 to t18, the tDQS2DQ monitoring module 100 may detect the skew between the data signal DQ and the data strobe signal DQS. For example, in response to the detection enable signal DEN at the 17th time point t17, the skew detection circuit 120 may detect the skew between the data signal DQ and the data strobe signal DQS. At the 18th time point t18, the tDQS2DQ monitoring module 100 may change the obtained skew value OSW to the skew value detected in the time period from t17 to t18. For example, at the 18th time point t18, the obtained skew value OSW may be changed to a fourth obtaining value OV4. At the 18th time point t18, the level of the detection enable signal DEN may be changed to the low level LOW.

After the 18th time point t18, the tDQS2DQ monitoring module 100 may compare the obtained skew value OSW and the reference skew value RSW. A difference between the fourth obtaining value OV4 and the reference value RV may be greater than the threshold value or may be out of the threshold range. At the 19th time point t19 at which the difference between the fourth obtaining value OV4 and the reference value RV is greater than the threshold value, the level of the flag “FLAG” may be changed to the high level HIGH. For example, based on a result of comparing the obtained skew value OSW and the reference skew value RSW at the 19th time point t19, the skew comparison circuit 140 may generate the flag “FLAG” or may change the level of the flag “FLAG” to the high level HIGH.

In some implementations, the tDQS2DQ monitoring module 100 may maintain a level of a signal after the 19th time point t19 and may return to a state before the 11th time point t11 in response to a new trace command TCMD. In some implementations, after an arbitrary time passes from the 19th time point t19 at which the level of the flag “FLAG” is changed, the tDQS2DQ monitoring module 100 may change levels of all the signals to the low level LOW.

In FIG. 8, description is given based on the case where the DQS training is performed at the 11th time point t11, but this is provided as an example. It should be understood that implementations in which the memory device 12 does not perform the DQS training or retraining at the 11th time point t11 (e.g., where the tDQS2DQ monitoring module 100 performs the operations of FIG. 8 based on a previously generated reference skew value) also belong to the scope of the present disclosure.

Time periods between the time points t11 to t19 illustrated in FIG. 8 should not be understood as corresponding to times actually taken to perform operations and should be understood as indicative of an order of operations. The change of the obtained skew value OSW of FIG. 8 is provided as an example, and the scope of the present disclosure is not limited thereto. For example, it should be understood that implementations in which the difference between the obtained skew value OSW and the reference skew value RSW is greater than the threshold value at a time point other than the 18th time point t18, and the level of the flag “FLAG” is thus correspondingly changed, also belong to the scope of the present disclosure.

FIG. 9 is a circuit diagram illustrating a first memory block among a plurality of memory blocks included in a memory cell array, e.g., the memory cell array of FIG. 3. A memory block having a three-dimensional structure will be described with reference to FIG. 9, but the present disclosure is not limited thereto. For example, a memory block according to the present disclosure may have a two-dimensional memory block structure. A first memory block BLK1 will be described with reference to FIG. 9, but the scope of the present disclosure is not limited thereto. The remaining memory blocks may be similar in structure to the first memory block BLK1 to be described with reference to FIG. 9.

In some implementations, the first memory block BLK1 to be described with reference to FIG. 9 may correspond to a physical erase unit of the memory device 12. However, the scope of the present disclosure is not limited thereto. For example, an erase unit may be changed to a page unit, a word line unit, a sub-block unit, etc.

Referring to FIG. 9, the first memory block BLK1 may include a plurality of cell strings CS11, CS12, CS21, and CS22. The plurality of cell strings CS11, CS12, CS21, and CS22 may be arranged in a row direction and a column direction to form rows and columns.

Each of the plurality of cell strings CS11, CS12, CS21, and CS22 includes a plurality of cell transistors. For example, each of the plurality of cell strings CS11, CS12, CS21, and CS22 may include string selection transistors SSTa and SSTb, a plurality of memory cells MC1 to MC9, ground selection transistors GSTa and GSTb, and dummy memory cells DMC1 and DMC2. In some implementations, each of a plurality of cell transistors included in the cell strings CS11, CS12, CS21, and CS22 may be a charge trap flash (CTF) memory cell.

In each cell string, the plurality of memory cells MC1 to MC9 are serially connected and are stacked in a direction perpendicular to a plane defined by the row direction and the column direction, that is, in a height direction. In each cell string, the string selection transistors SSTa and SSTb are serially connected and are interposed between a bit line BL1 or BL2 and the plurality of memory cells MC1 to MC9, and the ground selection transistors GSTa and GSTb are serially connected. The serially-connected ground selection transistors GSTa and GSTb are provided between the plurality of memory cells MC1 to MC9 and a common source line CSL.

In some implementations, in each cell string, the first dummy memory cell DMC1 may be provided between the plurality of memory cells MC1 to MC9 and the ground selection transistors GSTa and GSTb. In some implementations, in each cell string, the second dummy memory cell DMC2 may be provided between the plurality of memory cells MC1 to MC9 and the string selection transistors SSTa and SSTb.

The ground selection transistors GSTa and GSTb of the cell strings CS11, CS12, CS21, and CS22 may be connected in common with a ground selection line GSL. In some implementations, ground selection transistors in the same row may be connected to the same ground selection line, and ground selection transistors in different rows may be connected to different ground selection lines. For example, the first ground selection transistors GSTa of the cell strings CS11 and CS12 in the first row may be connected to a first ground selection line, and the first ground selection transistors GSTa of the cell strings CS21 and CS22 in the second row may be connected to a second ground selection line.

In some implementations, although not illustrated, ground selection transistors provided at the same height from a substrate (not illustrated) may be connected to the same ground selection line, and ground selection transistors provided at different heights therefrom may be connected to different ground selection lines.

Memory cells of the same height from the substrate or the ground selection transistors GSTa and GSTb are connected in common with the same word line, and memory cells of different heights therefrom are connected with different word lines. For example, the memory cells MC1 to MC9 of the cell strings CS11, CS12, CS21, and CS22 may be connected to first to ninth word lines WL1 to WL9.

String selection transistors, which belong to the same row, from among the first string selection transistors SSTa of the same height are connected to the same string selection line, and string selection transistors, which belong to another row, from among the first string selection transistors SSTa are connected to another string selection line. For example, the first string selection transistors SSTa of the cell strings CS11 and CS12 in the first row are connected in common to a string selection line SSL1a, and the first string selection transistors SSTa of the cell strings CS21 and CS22 in the second row are connected in common to a string selection line SSL1a.

Likewise, string selection transistors, which belong to the same row, from among the second string selection transistors SSTb at the same height are connected to the same string selection line, and string selection transistors, which belong to another row, from among the second string selection transistors SSTb are connected to another string selection line. For example, the second selection transistors SSTb of the cell strings CS11 and CS12 in the first row are connected in common to a string selection line SSL1b, and the second string selection transistors SSTb of the cell strings CS21 and CS22 in the second row are connected in common to a string selection line SSL2b.

In some implementations, dummy memory cells of the same height are connected to the same dummy word line, and dummy memory cells of different heights are connected with different dummy word lines. For example, the first dummy memory cells DMC1 are connected to a first dummy word line DWL1, and the second dummy memory cells DMC2 are connected to a second dummy word line DWL2.

The first memory block BLK1 illustrated in FIG. 9 is provided only as an example. The number of cell strings may increase or decrease, and the number of rows of cell strings and the number of columns of cell strings may increase or decrease depending on the number of cell strings. Also, the number of cell transistors GST, MC, DMC, and SST of the first memory block BLK1 may increase or decrease, and the height of the first memory block BLK1 may increase or decrease depending on the number of cell transistors. In addition, the number of lines GSL, WL, DWL, and SSL connected to the cell transistors may increase or decrease depending on the number of cell transistors.

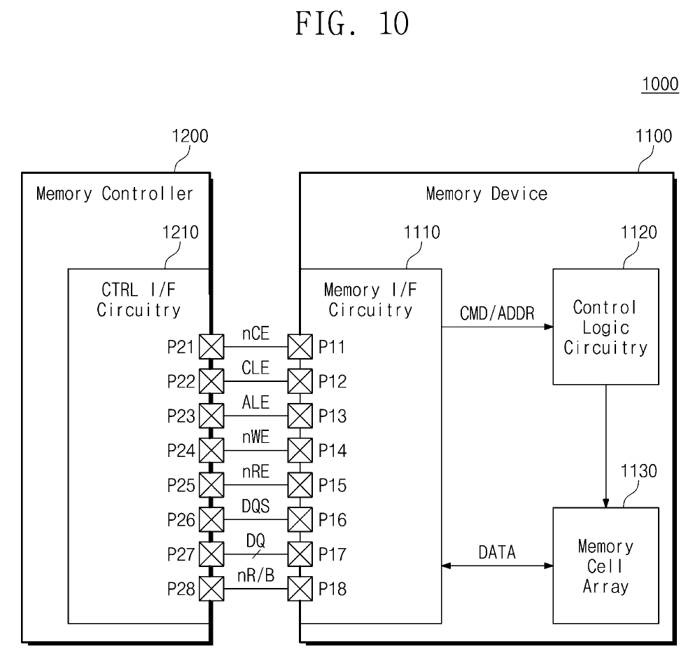

FIG. 10 is a block diagram illustrating an example of a memory system. Referring to FIG. 10, a memory system 1000 may include a memory device 1100 and a memory controller 1200. The memory controller 1200 may correspond to the controller 11 of FIG. 1.

The memory device 1100 may include first to eighth pins P11 to P18, a memory interface circuit 1110, a control logic circuit 1120, and a memory cell array 1130. In some implementations, the memory device 1100 may include the tDQS2DQ monitoring module 100 described with reference to FIGS. 1 to 8. For example, the memory interface circuit 1110 may include the tDQS2DQ monitoring module 100 described with reference to FIGS. 1 to 8.

The memory interface circuitry 1110 may receive a chip enable signal nCE from the memory controller 1200 through the first pin P11. The memory interface circuitry 1110 may transmit and receive signals to and from the memory controller 1200 through the second to eighth pins P12 to P18 in response to the chip enable signal nCE. For example, when the chip enable signal nCE is in an enable state (e.g., a low level), the memory interface circuitry 1110 may transmit and receive signals to and from the memory controller 1200 through the second to eighth pins P12 to P18.

The memory interface circuitry 1110 may receive a command latch enable signal CLE, an address latch enable signal ALE, and a write enable signal nWE from the memory controller 1200 through the second to fourth pins P12 to P14. The memory interface circuitry 1110 may receive a data signal DQ from the memory controller 1200 through the seventh pin P17 or transmit the data signal DQ to the memory controller 1200. A command CMD, an address ADDR, and data may be transmitted via the data signal DQ. For example, the data signal DQ may be transmitted through a plurality of data signal lines. In this case, the seventh pin P17 may include a plurality of pins respectively corresponding to a plurality of data signals DQ(s).

The memory interface circuitry 1110 may obtain the command CMD from the data signal DQ, which is received in an enable section (e.g., a high-level state) of the command latch enable signal CLE based on toggle time points of the write enable signal nWE. The memory interface circuitry 1110 may obtain the address ADDR from the data signal DQ, which is received in an enable section (e.g., a high-level state) of the address latch enable signal ALE based on the toggle time points of the write enable signal nWE.

In some implementations, the write enable signal nWE may be maintained at a static state (e.g., a high level or a low level) and toggle between the high level and the low level. For example, the write enable signal nWE may toggle in a section in which the command CMD or the address ADDR is transmitted. Thus, the memory interface circuitry 1110 may obtain the command CMD or the address ADDR based on toggle time points of the write enable signal nWE.

The memory interface circuitry 1110 may receive a read enable signal nRE from the memory controller 1200 through the fifth pin P15. The memory interface circuitry 1110 may receive a data strobe signal DQS from the memory controller 1200 through the sixth pin P16 or transmit the data strobe signal DQS to the memory controller 1200.

In a data (DATA) output operation of the memory device 1100, the memory interface circuitry 1110 may receive the read enable signal nRE, which toggles through the fifth pin P15, before outputting the data DATA. The memory interface circuitry 1110 may generate the data strobe signal DQS, which toggles based on the toggling of the read enable signal nRE. For example, the memory interface circuitry 1110 may generate a data strobe signal DQS, which starts toggling after a predetermined delay (e.g., tDQSRE), based on a toggling start time of the read enable signal nRE. The memory interface circuitry 1110 may transmit the data signal DQ including the data DATA based on a toggle time point of the data strobe signal DQS. Thus, the data DATA may be aligned with the toggle time point of the data strobe signal DQS and transmitted to the memory controller 1200.

In a data (DATA) input operation of the memory device 1100, when the data signal DQ including the data DATA is received from the memory controller 1200, the memory interface circuitry 1110 may receive the data strobe signal DQS, which toggles, along with the data DATA from the memory controller 1200. The memory interface circuitry 1110 may obtain the data DATA from the data signal DQ based on toggle time points of the data strobe signal DQS. For example, the memory interface circuitry 1110 may sample the data signal DQ at rising and falling edges of the data strobe signal DQS and obtain the data DATA.

The memory interface circuitry 1110 may transmit a ready/busy output signal nR/B to the memory controller 1200 through the eighth pin P18. The memory interface circuitry 1110 may transmit state information of the memory device 1100 through the ready/busy output signal nR/B to the memory controller 1200. When the memory device 1100 is in a busy state (i.e., when operations are being performed in the memory device 1100), the memory interface circuitry 1110 may transmit a ready/busy output signal nR/B indicating the busy state to the memory controller 1200. When the memory device 1100 is in a ready state (i.e., when operations are not performed or completed in the memory device 1100), the memory interface circuitry 1110 may transmit a ready/busy output signal nR/B indicating the ready state to the memory controller 1200. For example, while the memory device 1100 is reading data DATA from the memory cell array 1130 in response to a page read command, the memory interface circuitry 1110 may transmit a ready/busy output signal nR/B indicating a busy state (e.g., a low level) to the memory controller 1200. For example, while the memory device 1100 is programming data DATA to the memory cell array 1130 in response to a program command, the memory interface circuitry 1110 may transmit a ready/busy output signal nR/B indicating the busy state to the memory controller 1200.

The control logic circuitry 1120 may control all operations of the memory device 1100. The control logic circuitry 1120 may receive the command/address CMD/ADDR obtained from the memory interface circuitry 1110. The control logic circuitry 1120 may generate control signals for controlling other components of the memory device 1100 in response to the received command/address CMD/ADDR. For example, the control logic circuitry 1120 may generate various control signals for programming data DATA to the memory cell array 1130 or reading the data DATA from the memory cell array 1130.

The memory cell array 1130 may store the data DATA obtained from the memory interface circuitry 1110, via the control of the control logic circuitry 1120. The memory cell array 1130 may output the stored data DATA to the memory interface circuitry 1110 via the control of the control logic circuitry 1120.

The memory cell array 1130 may include a plurality of memory cells. For example, the plurality of memory cells may be flash memory cells. However, the memory type is not limited thereto, and the memory cells may be RRAM cells, FRAM cells, PRAM cells, thyristor RAM (TRAM) cells, or MRAM cells. Hereinafter, an example in which the memory cells are NAND flash memory cells will mainly be described.

The memory controller 1200 may include first to eighth pins P21 to P28 and a controller interface circuitry 1210. The first to eighth pins P21 to P28 may respectively correspond to the first to eighth pins P11 to P18 of the memory device 1100.

The controller interface circuitry 1210 may transmit a chip enable signal nCE to the memory device 1100 through the first pin P21. The controller interface circuitry 1210 may transmit and receive signals to and from the memory device 1100, which is selected by the chip enable signal nCE, through the second to eighth pins P22 to P28.

The controller interface circuitry 1210 may transmit the command latch enable signal CLE, the address latch enable signal ALE, and the write enable signal nWE to the memory device 1100 through the second to fourth pins P22 to P24. The controller interface circuitry 1210 may transmit or receive the data signal DQ to and from the memory device 1100 through the seventh pin P27.

The controller interface circuitry 1210 may transmit the data signal DQ including the command CMD or the address ADDR to the memory device 1100 along with the write enable signal nWE, which toggles. The controller interface circuitry 1210 may transmit the data signal DQ including the command CMD to the memory device 1100 by transmitting a command latch enable signal CLE having an enable state. Also, the controller interface circuitry 1210 may transmit the data signal DQ including the address ADDR to the memory device 1100 by transmitting an address latch enable signal ALE having an enable state.

The controller interface circuitry 1210 may transmit the read enable signal nRE to the memory device 1100 through the fifth pin P25. The controller interface circuitry 1210 may receive or transmit the data strobe signal DQS from or to the memory device 1100 through the sixth pin P26.

In a data (DATA) output operation of the memory device 1100, the controller interface circuitry 1210 may generate a read enable signal nRE, which toggles, and transmit the read enable signal nRE to the memory device 1100. For example, before outputting data DATA, the controller interface circuitry 1210 may generate a read enable signal nRE, which is changed from a static state (e.g., a high level or a low level) to a toggling state. Thus, the memory device 1100 may generate a data strobe signal DQS, which toggles, based on the read enable signal nRE. The controller interface circuitry 1210 may receive the data signal DQ including the data DATA along with the data strobe signal DQS, which toggles, from the memory device 1100. The controller interface circuitry 1210 may obtain the data DATA from the data signal DQ based on a toggle time point of the data strobe signal DQS.

In a data (DATA) input operation of the memory device 1100, the controller interface circuitry 1210 may generate a data strobe signal DQS, which toggles. For example, before transmitting data DATA, the controller interface circuitry 1210 may generate a data strobe signal DQS, which is changed from a static state (e.g., a high level or a low level) to a toggling state. The controller interface circuitry 1210 may transmit the data signal DQ including the data DATA to the memory device 1100 based on toggle time points of the data strobe signal DQS.

The controller interface circuitry 1210 may receive a ready/busy output signal nR/B from the memory device 1100 through the eighth pin P28. The controller interface circuitry 1210 may determine state information of the memory device 1100 based on the ready/busy output signal nR/B.

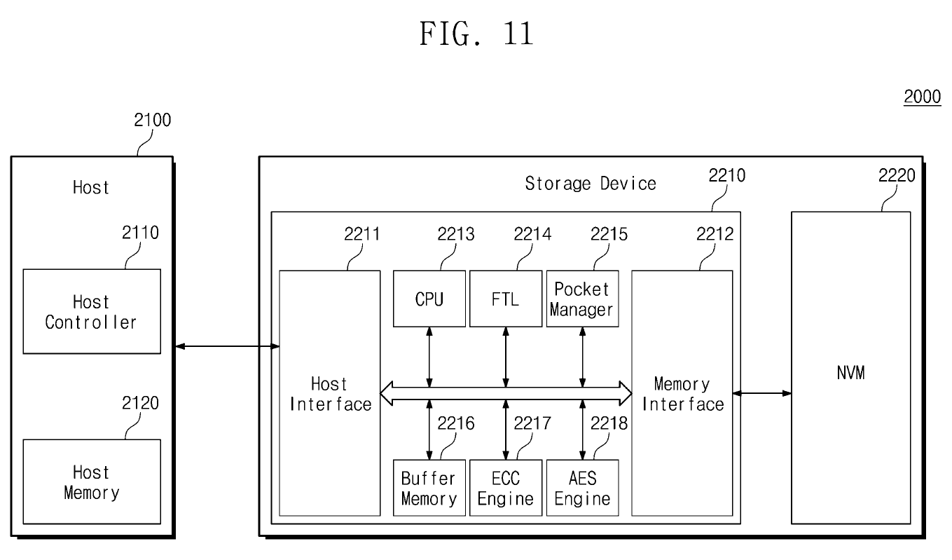

FIG. 11 is a block diagram of a host storage system 2000. The host storage system 2000 may include a host 2100 and a storage device 2200. Further, the storage device 2200 may include a storage controller 2210 and an NVM 2220. According to some implementations, the host 2100 may include a host controller 2110 and a host memory 2120. The host memory 2120 may serve as a buffer memory configured to temporarily store data to be transmitted to the storage device 2200 or data received from the storage device 2200.

The storage device 2200 may include storage media configured to store data in response to requests from the host 2100. As an example, the storage device 2200 may include at least one of an SSD, an embedded memory, and a removable external memory. When the storage device 2200 is an SSD, the storage device 2200 may be a device that conforms to an NVMe standard. When the storage device 2200 is an embedded memory or an external memory, the storage device 2200 may be a device that conforms to a UFS standard or an eMMC standard. Each of the host 2100 and the storage device 2200 may generate a packet according to an adopted standard protocol and transmit the packet.

When the NVM 2220 of the storage device 2200 includes a flash memory, the flash memory may include a 2D NAND memory array or a 3D (or vertical) NAND (VNAND) memory array. As another example, the storage device 2200 may include various other kinds of NVMs. For example, the storage device 2200 may include magnetic RAM (MRAM), spin-transfer torque MRAM, conductive bridging RAM (CBRAM), ferroelectric RAM (FRAM), PRAM, RRAM, and various other kinds of memories.

According to some implementations, the host controller 2110 and the host memory 2120 may be implemented as separate semiconductor chips. As another example, in some implementations, the host controller 2110 and the host memory 2120 may be integrated in the same semiconductor chip. As an example, the host controller 2110 may be any one of a plurality of modules included in an application processor (AP). The AP may be implemented as a System on Chip (SoC). Further, the host memory 2120 may be an embedded memory included in the AP or an NVM or memory module located outside the AP.

The host controller 2110 may manage an operation of storing data (e.g., write data) of a buffer region of the host memory 2120 in the NVM 2220 or an operation of storing data (e.g., read data) of the NVM 2220 in the buffer region.

The storage controller 2210 may include a host interface 2211, a memory interface 2212, and a CPU 2213. Further, the storage controllers 2210 may further include a flash translation layer (FTL) 2214, a packet manager 2215, a buffer memory 2216, an error correction code (ECC) engine 2217, and an advanced encryption standard (AES) engine 2218. The storage controllers 2210 may further include a working memory (not shown) in which the FTL 2214 is loaded. The CPU 2213 may execute the FTL 2214 to control data write and read operations on the NVM 2220.

The host interface 2211 may transmit and receive packets to and from the host 2100. A packet transmitted from the host 2100 to the host interface 2211 may include a command or data to be written to the NVM 2220. A packet transmitted from the host interface 2211 to the host 2100 may include a response to the command or data read from the NVM 2220. The memory interface 2212 may transmit data to be written to the NVM 2220 to the NVM 2220 or receive data read from the NVM 2220. The memory interface 2212 may be configured to comply with a standard protocol, such as Toggle or open NAND flash interface (ONFI).

The FTL 2214 may perform various functions, such as an address mapping operation, a wear-leveling operation, and a garbage collection operation. The address mapping operation may be an operation of converting a logical address received from the host 2100 into a physical address used to actually store data in the NVM 2220. The wear-leveling operation may be a technique for preventing excessive deterioration of a specific block by allowing blocks of the NVM 2220 to be uniformly used. As an example, the wear-leveling operation may be implemented using a firmware technique that balances erase counts of physical blocks. The garbage collection operation may be a technique for ensuring usable capacity in the NVM 2220 by erasing an existing block after copying valid data of the existing block to a new block.

The packet manager 2215 may generate a packet according to a protocol of an interface, which consents to the host 2100, or parse various types of information from the packet received from the host 2100. In addition, the buffer memory 2216 may temporarily store data to be written to the NVM 2220 or data to be read from the NVM 2220. Although the buffer memory 2216 may be a component included in the storage controllers 2210, the buffer memory 2216 may be outside the storage controllers 2210.

The ECC engine 2217 may perform error detection and correction operations on read data read from the NVM 2220. More specifically, the ECC engine 2217 may generate parity bits for write data to be written to the NVM 2220, and the generated parity bits may be stored in the NVM 2220 together with write data. During the reading of data from the NVM 2220, the ECC engine 2217 may correct an error in the read data by using the parity bits read from the NVM 2220 along with the read data, and output error-corrected read data.

The AES engine 2218 may perform at least one of an encryption operation and a decryption operation on data input to the storage controllers 2210 by using a symmetric-key algorithm.

The nonvolatile memory 2220 may correspond to (e.g., include) the memory device 12 described with reference to FIGS. 1 to 9. In some implementations, the nonvolatile memory 2220 may include the tDQS2DQ monitoring module 100 described with reference to FIGS. 1 to 8.

In the foregoing description, components which are described with reference to the terms “~unit”, “~module”, “~block”, “~er or ~or”, “circuit”, “circuitry”, etc. and function blocks which are illustrated in drawings, may be implemented in the form of software or hardware or in the form of a combination thereof. In some implementations, the software may be a machine code, firmware, an embedded code, a source code, application software, and/or a combination thereof or may include the listed components. In some implementations, the hardware may include an electrical circuit, an electronic circuit (e.g., an analog circuit or a digital circuit), a processor, a computer, an integrated circuit, integrated circuit cores, a pressure sensor, an inertial sensor, a microelectromechanical system (MEMS), a passive element, and or a combination thereof or may include the listed components.

Accordingly, as described above, a memory device which is capable of monitoring whether to need to train a data strobe signal, based on a skew monitoring module and notifying a controller that the training of the data strobe signal is required when the training of the data strobe signal is required, is provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array; and
a monitoring module comprising:
a skew detection circuit configured to detect a first skew value between a data signal and a data strobe signal,
a reference skew latch circuit configured to store a reference skew value, and
a skew comparison circuit configured to:
compare the first skew value and the reference skew value, to obtain a comparison result, and
generate a data strobe training flag based on the comparison result.

2. The memory device of claim 1, wherein the skew comparison circuit is configured to, based on a difference between the first skew value and the reference skew value being greater than a threshold value, set the data strobe training flag to a level indicating that data strobe training is to be performed.

3. The memory device of claim 1, wherein the skew detection circuit is configured to periodically detect a skew value between the data signal and the data strobe signal.

4. The memory device of claim 1, wherein the memory device is configured to perform data strobe training during a first time period, and
wherein the monitoring module is configured to, at a second time after the first time period, detect a second skew value between the data signal and the data strobe signal,
wherein the reference skew value comprises the second skew value.

5. The memory device of claim 1, wherein the skew comparison circuit is configured to, based on a difference between the first skew value and the reference skew value being less than a threshold value, maintain the data strobe signal at a constant level.

6. The memory device of claim 1, wherein the monitoring module comprises:
a training control circuit configured to control a detection operation in which the first skew value is detected.

7. The memory device of claim 6, wherein the training control circuit is configured to generate a detection enable signal that causes the skew detection circuit to detect the first skew value.

8. The memory device of claim 7, wherein the skew comparison circuit is configured to:
generate an internal enable signal based on the comparison result; and
transmit the internal enable signal to the training control circuit.

9. The memory device of claim 8, wherein the training control circuit is configured to change a level of the detection enable signal in based on the internal enable signal.

10. The memory device of claim 1, wherein the memory device is configured to:
based on the data strobe training flag, receive a first command from a controller; and perform data strobe training in response to the first command.

11. An operation method of a memory device, the method comprising:
performing data strobe training to generate a reference skew value between a data signal and a data strobe signal;
detecting a first skew value between the data signal and the data strobe signal;
comparing the reference skew value and the first skew value; and
based on a difference between the reference skew value and the first skew value being greater than a threshold value, setting a data strobe training flag to a level indicating that data strobe training is to be performed.

12. The method of claim 11, comprising:
receiving a data strobe training command based on the level of the data strobe training flag; and
performing additional data strobe training in response to the data strobe training command.

13. The method of claim 11, comprising:
periodically detect a skew value between the data signal and the data strobe signal.

14. The method of claim 11, wherein the memory device includes a monitoring module, and wherein the method comprises:
using a detection control circuit of the monitoring module to control detection of the first skew value;
using a skew detection circuit of the monitoring module to detect the first skew value; and
using a skew comparison circuit of the monitoring module to:
compare the reference skew value and the first skew value, and
change the level of the data strobe training flag.

15. The method of claim 14, comprising, using the skew comparison circuit:
comparing a second skew value and the reference skew value, to generate a comparison result;
generating an internal enable signal based on the comparison result; and
transmitting the internal enable signal from the skew comparison circuit to the detection control circuit.

16. The method of claim 15, wherein detecting the first skew value is based on a detection enable signal, and
wherein the method comprises changing a level of the detection enable signal based on the internal enable signal and based on a trace command received from a controller.

17. The method of claim 14, comprising:
providing the reference skew value from a skew latch circuit of the monitoring module to a reference skew latch circuit of the monitoring module;
storing the reference skew value in the reference skew latch circuit;
providing the reference skew value from the reference skew latch circuit to the skew comparison circuit;
storing the first skew value in the skew latch circuit; and
providing the first skew value from the skew latch circuit to the skew comparison circuit.

18. A storage device comprising:
a memory device configured to store data, wherein the memory device comprises a monitoring module; and
a controller configured to control the memory device and to exchange a data signal and a data strobe signal with the memory device,
wherein the monitoring module is configured to:
generate a reference skew value between the data signal and the data strobe signal, wherein the reference skew value is generated as a result of data strobe training performed by the memory device,
detect a first skew value between the data signal and the data strobe signal, and
generate a data strobe training flag based on a comparison between the reference skew value and the first skew value,
wherein the controller is configured to provide a data strobe training command to the memory device based on the data strobe training flag, and
wherein the monitoring module is configured to perform additional data strobe training in response to the data strobe training command.

19. The storage device of claim 18, wherein the monitoring module is configured to periodically generate skew values.

20. The storage device of claim 18, wherein the controller is configured to provide the data strobe training command based on the data strobe training flag having a predetermined level.
